(19) United States
(12) Patent Application Publication
(10) Pub. No.: US 2026/0247894 A1
(43) Pub. Date: Aug. 20, 2026

(54) METHOD FOR MANUFACTURING A WAFER AND METHOD FOR MANUFACTURING A BONDED WAFER

(71) Applicant: DISCO CORPORATION, Tokyo (JP)

(72) Inventors: Kazuya Hirata, Tokyo (JP); Haruna Yano, Tokyo (JP)

(21) Appl. No.: 19/459,613

(22) Filed: Jan. 26, 2026

(30) Foreign Application Priority Data
Feb. 17, 2025 (JP) 2025-023003

(51) Int. Cl. H10P 54/30; H10P 10/00; H10P 52/00

(52) U.S. Cl. CPC H10P 54/30; H10P 10/12; H10P 52/00

(57) ABSTRACT

A method for manufacturing a wafer includes a supporting step, which includes adhering or bonding a surface of a first wafer on one side and a surface of a supporting substrate on one side to each other to arrange the first wafer to be supported on the supporting substrate; a lateral-surface processing step, which includes emitting a laser beam onto a lateral surface of the first wafer supported on the supporting substrate to form the lateral surface of the first wafer into a shape having a predetermined cross section; and a grinding step which includes griding a surface of the first wafer on the other side, the grinding step being performed before or after the lateral-surface processing step.

### CROSS REFERENCE TO RELATED APPLICATION

This application is based upon and claims the benefit of priority from the prior Japanese Patent Application No. 2025-023003, filed on February 17, 2025; the entire contents of which are incorporated herein by reference.

### FIELD

The present disclosure relates to a method for manufacturing a wafer, in which an outer periphery of the wafer is processed, and a method for manufacturing a bonded wafer.

### BACKGROUND

Japanese Patent Application Laid-Open Publication No. 2020-040181 discloses an edge trimming apparatus, which processes a wafer by cutting and removing a chamfering portion at an outer peripheral edge with a cutting blade. According to this edge trimming apparatus, as taught in Japanese Patent Application Laid-Open Publication No. 2015-030089, when a tip of the cutting blade is worn unevenly, the portion to be chamfered may not be removed entirely. In order to avoid such defect, as disclosed in Japanese Patent Application Laid-Open Publication No. 2013-082021, the tip of the cutting blade may be dressed and shaped preferably.

### SUMMARY

However, dressing a tip of a cutting blade involves a problem such that shaping of a tip completely takes a long time.

Meanwhile, in a bonded wafer where two wafers having a same diameter are bonded, one of the wafers may protrude from another due to, for example, dimensional tolerance ranges of the wafers. When such a bonded wafer is rotated during a manufacturing process, the protruding outer periphery of the one wafer may flutter, potentially causing chipping in the outer periphery. Therefore, there is a need for ability to process the outer periphery of the wafer efficiently to eliminate the protrusion.

The present disclosure has been made in consideration of these problems, and one of its objects is to provide a method for manufacturing a wafer and a method for manufacturing a bonded wafer that enable processing of an outer periphery of a wafer and shortening a time required for the processing.

According to an aspect of the present disclosure, a method for manufacturing a wafer includes a supporting step, which includes adhering or bonding a surface of a first wafer on one side and a surface of a supporting substrate on one side to each other to arrange the first wafer to be supported on the supporting substrate; a lateral-surface processing step, which includes emitting a laser beam onto a lateral surface of the first wafer supported on the supporting substrate to form the lateral surface of the first wafer into a shape having a predetermined cross section; and a grinding step, which includes griding a surface of the first wafer on the other side, the grinding step being performed before or after the lateral-surface processing step.

According to another aspect of the present disclosure, a method for manufacturing a bonded wafer, in which a first wafer and a second wafer are bonded, includes a bonding step, which includes bonding or adhering a surface of the first wafer on one side and a surface of the second wafer on one side to each other; and a lateral-surface processing step, which includes emitting a laser beam onto a lateral surface of the first wafer to process the lateral surface of the first wafer, the lateral-surface processing step being performed after the bonding step.

According to the present disclosure, the first wafer is processed with the laser beam emitted onto the lateral surface thereof. Therefore, compared with the conventional process where the cutting blade is used, dressing may be omitted, and time required for processing the wafer may be shortened. This allows efficient processing of the first wafer to change a cross-sectional shape of the lateral surface of the first wafer or reduce a diameter of the first wafer.

### BRIEF DESCRIPTION OF THE DRAWINGS

FIGS. 1A-1B are illustrative views of a bonding step and FIGS. 1C-1D are illustrative views of a lateral-surface processing step in a method for manufacturing a bonded wafer according to a first embodiment of the present disclosure.

FIGS. 2A-2B are illustrative views of a surface processing step and FIG. 2C is an illustrative view of a chamfering step in a method for manufacturing a bonded wafer according to a second embodiment of the present disclosure.

FIG. 3A is an illustrative view of a lateral-surface processing step and FIGS. 3B-3C are illustrative views of a surface processing step in a method for manufacturing a bonded wafer according to a third embodiment of the present disclosure.

FIGS. 4A-4B are illustrative views of a surface processing step and FIG. 4C is an illustrative view of a lateral-surface processing step in a method for manufacturing a bonded wafer according to a fourth embodiment of the present disclosure.

FIG. 5 is an illustrative view of a lateral-surface processing step according to a modified example.

### DESCRIPTION OF EMBODIMENTS

### First Embodiment

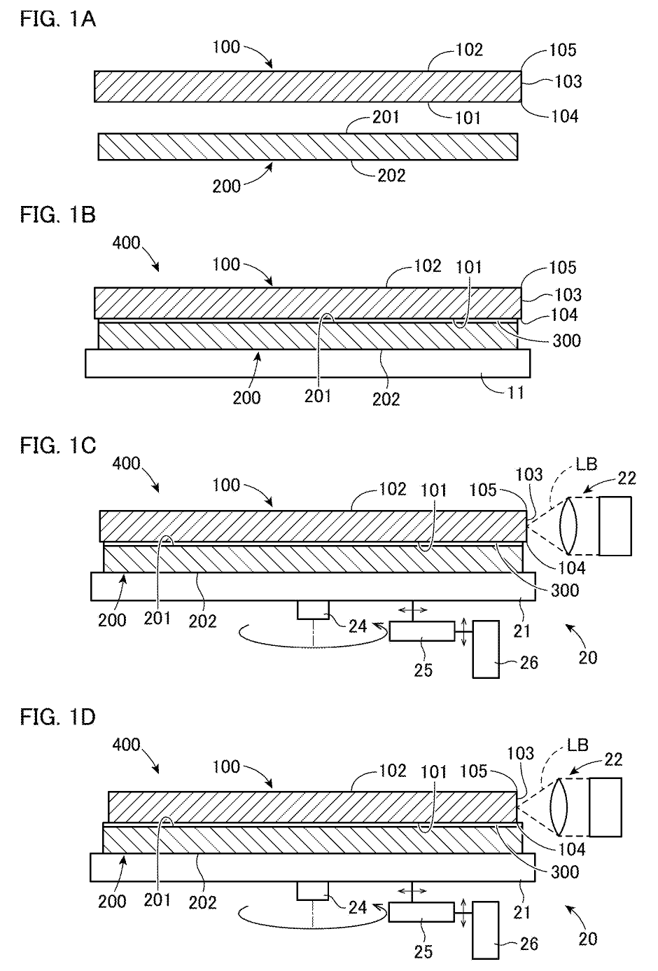

Hereinafter, with reference to the accompanying drawings, the method for manufacturing a bonded wafer according to the first embodiment of the present disclosure will be described with reference to FIGS. 1A-1D. FIGS. 1A-1B are illustrative views of a bonding step and FIGS. 1C-1D are illustrative views of a lateral-surface processing step. In the method for manufacturing a bonded wafer according the first embodiment, the bonding step and the lateral-surface processing step are performed sequentially. Note that the steps illustrated in the drawings in the embodiments below are merely examples, and the configuration of the steps is not limited thereto. Note, further, in the drawings including FIGS. 1B-1D, hatching in a cross section of a bonding layer 300, which will be described later, is omitted.

### Bonding Step

In the bonding step, first, a disk-shaped first wafer 100 and a disk-shaped second wafer 200 as shown in FIG. 1A are prepared. The first wafer 100 and the second wafer 200 are, typically, formed of a semiconductor such as silicon (Si).

The first wafer 100 includes a first front surface 101 and a first back surface 102, which are surfaces spreading orthogonally to a thickness direction. The first front surface 101 may be referred to as a surface of the first wafer 100 on one side, and the first back surface 102 may be referred to as a surface of the first wafer 100 on the other side. The second wafer 200 includes a second front surface 201 and a second back surface 202, which are surfaces spreading orthogonally to the thickness direction. The second front surface 201 may be referred to as a surface of the second wafer 200 on one side, and the second back surface 202 may be referred to as a surface of the second wafer 200 on the other side.

As shown in FIG. 1A, the first wafer 100 is set in place such that the first front surface 101 faces downward and the first back surface 102 faces upward, and the second wafer 200 is set in place such that the second front surface 201 faces upward and the second back surface 202 faces downward. In the first wafer 100, a lateral surface 103 is formed along an outer peripheral edge, and the lateral surface 103 is formed to be orthogonal to the first front surface 101 and the first back surface 102. At an intersection between the first front surface 101 and the lateral surface 103 and at an intersection between the first back surface 102 and the lateral surface 103, corners 104, 105 that are substantially right angle are formed.

In the bonding step, as shown in FIG. 1B, the second wafer 200 is held on a chuck table 11, with the second back surface 202 facing downward. Before or after the second wafer 200 is set on the chuck table 11, an insulating film is formed on the second front surface 201 of the second wafer 200. Thereafter, the insulating film is exposed to argon gas (a noble gas) so that a surface of the insulating film is activated. Meanwhile, an insulating film is also formed on the first front surface 101 of the first wafer 100. Thereafter, the insulating film is exposed to the argon gas so that a surface of the insulating film is activated. After the first front surface 101 of the first wafer 100 is set to face the second front surface 201 of the second wafer 200, the first front surface 101 of the first wafer 100 is pressed against the second front surface 201 of the second wafer 200 so that the activated first front surface 101 and the second front surface 201 fit each other closely. Accordingly, interatomic stress acts so that the first front surfaces 101, 201 of the first wafer 100 and the second wafer 200 are bonded, thereby forming a bonded wafer 400. A bonding layer 300 that bonds the first wafer 100 and the second wafer 200 in the bonded wafer 400 includes the insulating film on the first front surface 101 of the first wafer 100 and the insulating film on the second front surface 201 of the second wafer 200.

It is noted that, in the present embodiment, due to dimensional tolerances of the first wafer 100 and the second wafer 200, the first wafer 100 has a larger diameter than the second wafer 200. Accordingly, in the bonded wafer 400, the lateral surface 103 of the first wafer 100 protrudes outward from an outer periphery of the second wafer 200.

Optionally, the bonding member to form the bonding layer 300 may be, for example, a double-sided adhesive sheet, which is an adhesive agent in a form of a circular sheet. For another example, other than the double-sided adhesive sheet, a circular double-sided adhesive tape may be used. For another example, further, the bonding layer 300 may be formed by applying an adhesive agent or a liquid resin to the second front surface 201 of the second wafer 200 and bonding the first wafer 100 thereto. As such, in the bonding step, the first and second front surfaces 101, 201 of the first wafer 100 and the second wafer 200 may be attached to form the bonded wafer 400.

### Lateral-Surface Processing Step

After the bonding step is completed, as shown in FIGS. 1C-1D, a lateral-surface processing step is performed with a laser processing apparatus 20. Note that the laser processing apparatus 20 may have any configuration capable of performing the laser processing step of the present embodiment, and is not limited to the configuration shown in FIGS. 1C and 1D.

As shown in FIGS. 1C-1D, the laser processing apparatus 20 is configured to process the lateral surface 103 of the first wafer 100 with laser by relatively moving the chuck table 21 that holds the bonded wafer 400 and a laser emitter 22 that emits a laser beam LB.

The laser emitter 22 emits the laser beam LB oscillated from a laser oscillator (not shown) toward the lateral surface 103 of the first wafer 100 in the bonded wafer 400 that is held on the chuck table 21. The laser emitter 22 includes an optical system such as a mirror or a lens for guiding a pulsed laser beam LB emitted from the laser oscillator to the first wafer 100 and focuses the laser beam LB on the first wafer 100. The laser oscillator may include, for example, a laser medium such as Nd:YAG suitable for laser oscillation and generate the pulsed laser beam LB having a wavelength absorbable by the first wafer 100 at a predetermined repetition frequency. The laser emitter 22 emits and focuses the laser beam LB on the first wafer 100 from a lateral side of the chuck table 21.

The laser processing apparatus 20 further includes a rotation mechanism 24 that rotates the chuck table 21 around an axis extending in a vertical direction; a horizontal movement mechanism 25 that moves the chuck table 21 in, for example, horizontal orthogonal two-axis directions; and a vertical movement mechanism 26 that move the chuck table 21 in a vertical direction.

The rotation mechanism 24 includes a drive motor and a pulley mechanism (not shown) and rotates the chuck table 21 around the axis extending in the vertical direction. The horizontal movement mechanism 25 and the vertical movement mechanism 26 may employ any structures optionally using, for example, a cylinder, a motor, a slider, and/or a ball screw.

In the lateral-surface processing step, first, the bonded wafer 400 is held on the chuck table 21 such that the second back surface 202 of the second wafer 200 faces downward. Thereafter, the chuck table 21 and the bonded wafer 400 are rotated by driving of the rotation mechanism 24. While the rotation is continued, the laser emitter 22 emits the laser beam LB having the absorbable wavelength toward the lateral surface 103 of the first wafer 100 in the bonded wafer 400. The emitted laser beam LB is focused on the lateral surface 103 of the first wafer 100 through a condensing lens (not shown). In other words, a relative position between the first wafer 100 being rotated and the laser emitter 22 is adjusted by moving the chuck table 21 through the driving of the horizontal movement mechanism 25 and the vertical movement mechanism 26 so that the laser beam LB is focused on the lateral surface 103.

When the lateral surface 103 is irradiated with the laser beam LB, a portion forming the lateral surface 103 of the first wafer 100 sublimates and is ablated. Accordingly, as shown in FIG. 1D, the portion forming the lateral surface 103 of the first wafer 100 is removed, and a diameter of the first wafer 100 is reduced. Optionally, air may be jetted at the portion to be ablated to prevent the molten material of the first wafer 100 from adhering to the newly formed lateral surface 103 (the lateral surface of the first wafer 100 with a reduced diameter) and to prevent the first wafer 100 from being thermally deformed by the ablation.

In the lateral-surface processing step according to the present embodiment, the entire range of the first wafer 100 in the thickness direction is subjected to the ablation so that the diameter of the first wafer 100 is uniformly reduced throughout the entire range in the thickness direction. In order to process the first wafer 100 as above, the chuck table 21 is repeatedly raised and lowered by driving of the vertical movement mechanism 26, and the focusing position of the laser beam LB is moved to reciprocate in the vertical direction (i.e., the thickness direction of the first wafer 100). Meanwhile, the horizontal movement mechanism 25 is driven so that the focusing position of the laser beam LB gradually shifts toward a center of the first wafer 100 in accordance with progress of the ablation. Thus, even after the lateral-surface processing step is performed, forms of the corners 104, 105 are maintained to be substantially right angle at the intersection between the first front surface 101 and the lateral surface 103 and at the intersection between the first back surface 102 and the lateral surface 103.

Note that ablation processing refers to a phenomenon in which, when irradiation intensity with the laser beam LB becomes equal to or higher than a predetermined processing threshold, the laser is converted into electronic, thermal, photochemical, and mechanical energy on a solid surface, resulting in explosive release of neutral atoms, molecules, positive and negative ions, radicals, clusters, electrons, and light, which etches the solid surface.

According to the first embodiment described above, the first wafer 100 is processed so as to reduce a diameter of the first wafer 100 by irradiating the lateral surface 103 of the first wafer 100 with the laser beam LB. Accordingly, the conventional dressing process using a cutting blade may be eliminated, and time required for processing the lateral surface 103 is shortened and the bonded wafer 400 may be efficiently manufactured.

Further, by reducing the diameter of the first wafer 100, the first wafer 100 may be formed so as not to protrude from the outer periphery of the second wafer 200. Accordingly, even when the bonded wafer 400 is rotated at a high speed while being processed, fluttering may not occur at the outer periphery of the first wafer 100, and chipping of the outer periphery may be avoided.

While the diameter of the first wafer 100 is reduced, further, the corners 104, 105 may optionally be chamfered by emitting the laser beam LB in the same manner as in a chamfering process in a second embodiment, which will be described later. That is, even when a chamfered portion is not formed in the first wafer 100 before reducing the diameter, the chamfered portion may be formed at the time when being processed to reduce the diameter.

Next, more embodiments other than the first embodiment of the present disclosure will be described. In the following description, the same reference numerals may be used for components that are identical or equivalent to those in the embodiment(s) described earlier, and description of those components may be omitted or simplified.

### Second Embodiment

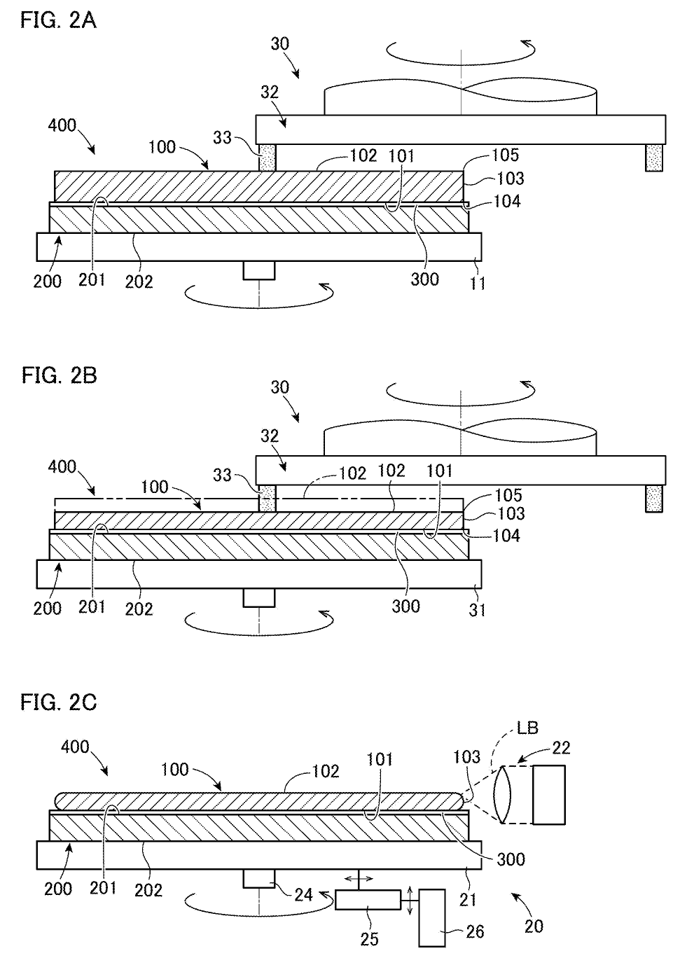

Next, a second embodiment of the present disclosure will be described with reference to FIGS. 2A-2C. FIGS. 2A-2B are illustrative views of a surface processing step, and FIG. 2C is an illustrative view of a chamfering step. In the second embodiment, a bonding step and a lateral-surface processing step are performed similarly to those described in the first embodiment, and thereafter, the surface processing step and the chamfering step described below are performed sequentially.

### Surface Processing Step

In the second embodiment, as shown in FIGS. 2A-2B, the surface processing step is performed with a grinding mechanism 30 after completion of the lateral-surface processing step described above. In the surface processing step, the bonded wafer 400 is held on a chuck table 31 of the grinding mechanism 30, with the second back surface 202 of the second wafer 200 facing downward.

Thereafter, the grinding mechanism 30 is set at a position where a part of grinding grindstones 33 arranged annularly on a grinding wheel 32 faces the first back surface 102, which is facing upward, of the first wafer 100. Thereafter, while the chuck table 31 and the grinding wheel 32 are each rotated around a vertical axis, the lower surface of the grinding grindstones 33 is pressed against the first back surface 102 of the first wafer 100. Accordingly, the first back surface 102 of the first wafer 100 is ground with the grindstones 33 so that the first wafer 100 is thinned to a predetermined thickness.

Even after the surface processing step is performed, forms of the corners 104, 105 at the intersection between the first front surface 101 and the lateral surface 103 and at the intersection between the first back surface 102 and the lateral surface 103 are maintained in the first wafer 100.

While the first wafer 100 is ground with the grindstones 33 in the grinding mechanism 30 in the above surface processing step, various modifications may be applied. For example, the first back surface 102 of the first wafer 100 may be polished by a rotating polishing pad (e.g., dry polishing, wet polishing, or CMP) or may be etched by plasma etching to remove irregularities on the first back surface 12.

### Chamfering Step

After the surface processing step is performed, the chamfering step is performed to chamfer the corners 104, 105 of the first wafer 100. The chamfering step is performed by the same or a similar laser processing apparatus 20 as that used in the lateral-surface processing step.

In the chamfering step, similarly to the lateral-surface processing step, the bonded wafer 400 is held on and rotated by the chuck table 21, and the laser beam LB having the absorbable wavelength is emitted from the laser emitter 22 onto the lateral surface 103 of the first wafer 100. By being irradiated with the laser beam LB, the corners 104, 105 of the lateral surface 103 of the first wafer 100 are chamfered into R shapes forming arcs in a cross-sectional view. In other words, the relative position between the lateral surface 103 of the first wafer 100 and the laser emitter 22 is adjusted through the driving of the horizontal movement mechanism 25 and the vertical movement mechanism 26 in order to irradiate and ablate the lateral surface 103 of the first wafer 100 with the laser beam LB into the above-described shape.

According to the second embodiment described above, when manufacturing the bonded wafer 400,the surface-processing step may be also included grinding process to thin the first wafer 100,and polishing or etching process to remove irregularities on the first back surface 102. Further, after these processes, the corners 104, 105 of the first wafer 100 may be chamfered in the chamfering step so that chipping or cracking at the outer periphery of the first wafer 100 may be prevented effectively.

### Third Embodiment

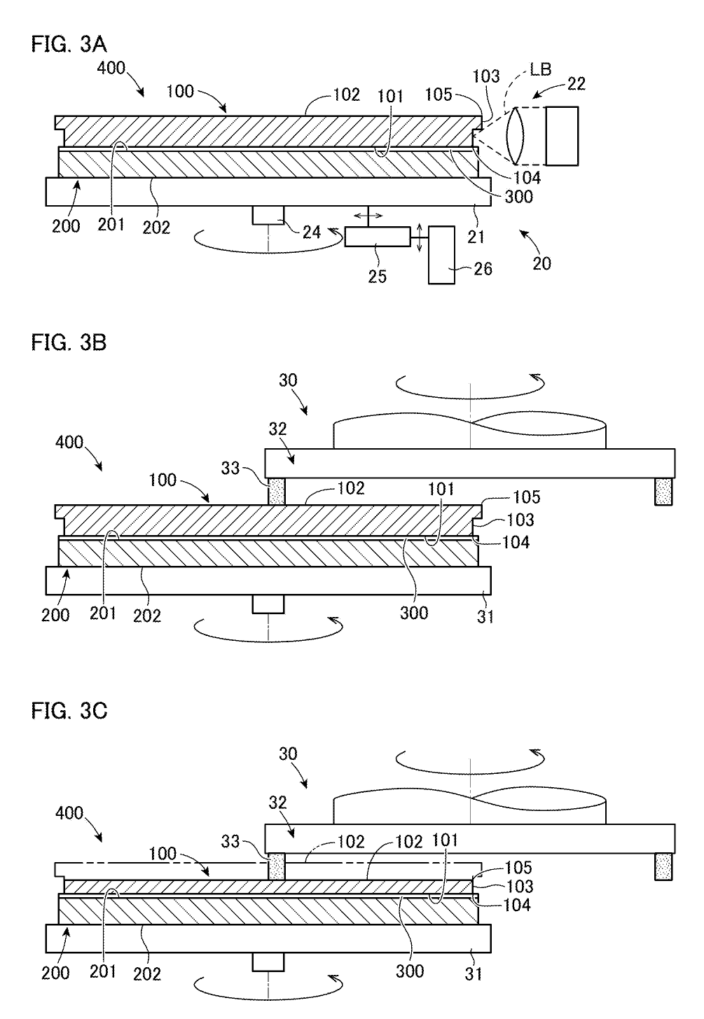

Next, a third embodiment of the present disclosure will be described with reference to FIGS. 3A-3C. FIG. 3A is an illustrative view of a lateral-surface processing step, and FIGS. 3B-3C are illustrative views of a surface processing step. According to the third embodiment, the shape of the lateral surface 103 after being processed in the lateral-surface processing step is different from that in the first embodiment, and the surface processing step as described in the second embodiment is performed.

### Lateral-Surface Processing Step

In the lateral-surface processing step according to the third embodiment, as shown in FIG. 3A, the lateral surface 103 of the first wafer 100 is ablated so that the diameter of the first wafer 100 is reduced partly within the range of the lateral surface 103 in the thickness direction. As shown in FIG. 3A, a portion of the lateral surface 103 toward the first front surface 101 in the thickness direction of the first wafer 100 is ablated by irradiation with the laser beam LB so that the diameter of the first wafer 100 becomes smaller on the side toward the first front surface 101, and the side toward the first back surface 102 remains unprocessed without the irradiation with the laser beam LB. In other words, a relative position between the lateral surface 103 of the first wafer 100 and the laser emitter 22 is adjusted through the driving of the horizontal movement mechanism 25 and the vertical movement mechanism 26 at the time of the laser beam LB emission from the laser emitter 22 so that first wafer 100 is processed through ablation as above.

### Surface Processing Step

After completion of the lateral-surface processing step, as shown in FIGS. 3B and 3C, the surface processing step is performed with the grinding mechanism 30 so that the first back surface 102 of the first wafer 100 is ground by the grindstones 33 being rotated. In the surface processing step according to the third embodiment, the first wafer 100 is ground to the position in the thickness direction where the diameter was reduced in the lateral-surface processing step. As such, at the first back surface 102 side of the first wafer 100, the unprocessed thickness portion, which remains unprocessed without being irradiated with the laser beam LB, is entirely removed.

According to the third embodiment described above, as compared with the first embodiment, an amount of removal from the first wafer 100 by irradiation with the laser beam LB in the lateral-surface processing step may be reduced. Meanwhile, according to the third embodiment, the first wafer after being ground in the surface processing step may be formed to have the uniform diameter throughout the thickness thereof, in contrast to the second embodiment (see FIGS. 2B and 3C). Therefore, according to the third embodiment, when processing the first wafer 100 to the diameter shown in FIGS. 2B or 3C, the amount of first wafer 100 to be removed is reduced, thereby shortening the processing time in the side processing step.

### Fourth Embodiment

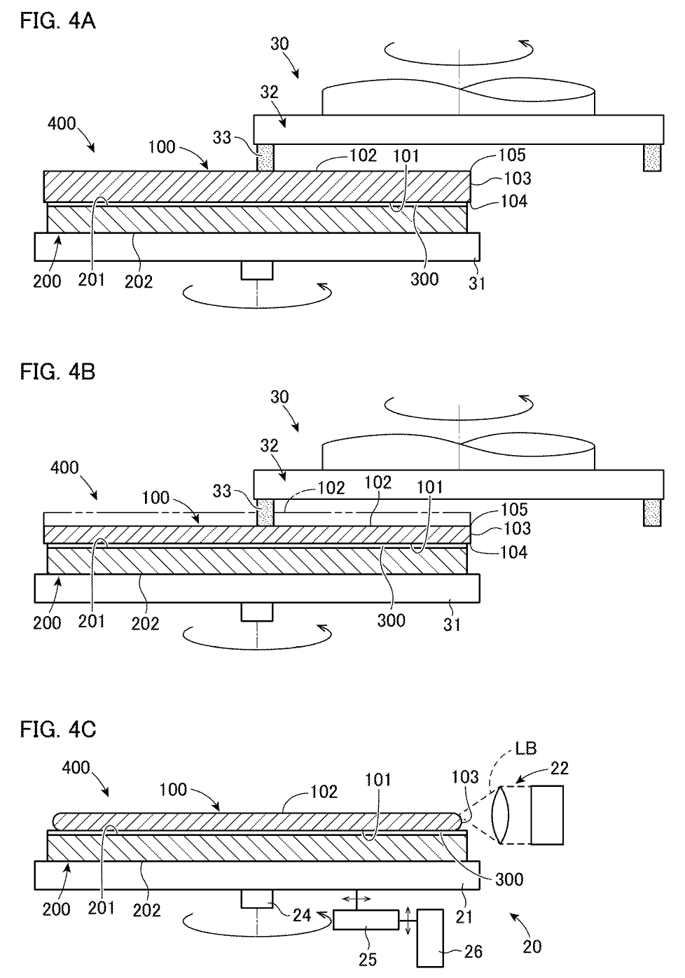

Next, a fourth embodiment of the present disclosure will be described with reference to FIGS. 4A-4C. FIGS. 4A-4B are illustrative views of a surface processing step, and FIG. 4C is an illustrative view of a lateral-surface processing step. In the fourth embodiment, the bonding step as described in the first embodiment is performed, and thereafter, a surface processing step and a lateral-surface processing step are performed in this order. In other words, the surface processing step is performed before the lateral-surface processing step.

### Surface Processing Step

As shown in FIGS. 4A and 4B, the surface processing step is performed with the grinding mechanism 30 in a state where the lateral surface 103 of the first wafer 100 protrudes outward from the outer periphery of the second wafer 200 in the bonded wafer 400. The surface processing step is performed similarly to the surface processing step in the second embodiment, except that the shape of the first wafer 100 in the bonded wafer 400 is different, and the first wafer 100 is thinned to a predetermined thickness.

### Lateral-Surface Processing Step

The lateral-surface processing step is performed with the laser processing apparatus 20 after the surface processing step is performed. In the lateral-surface processing step, the bonded wafer 400 is held and rotated by the chuck table 21, and the laser beam LB having the absorbable wavelength is emitted from the laser emitter 22 onto the lateral surface 103 of the first wafer 100. By irradiation with the laser beam LB, the diameter of the first wafer 100 is reduced entirely throughout the range in the thickness direction, and further, the lateral surface 103 of the first wafer 100 is ablated such that the both corners 104, 105 are chamfered into arc shapes in the cross-sectional view. In other words, the relative position between the lateral surface 103 of the first wafer 100 and the laser emitter 22 is adjusted by the driving of the horizontal movement mechanism 25 and the vertical movement mechanism 26 in order to process the lateral surface 103 of the first wafer 100 by irradiation and ablation with the laser beam LB into the above-described shape.

According to the fourth embodiment described above, in the lateral-surface processing step, the diameter of the first wafer 100 may be reduced and the lateral surface 103 may be chamfered simultaneously, whereby the processing time may be shortened.

Note that embodiment of the present disclosure may not necessarily be limited to the configuration described above but may be modified in various ways. In the embodiments described above, sizes or forms of the components illustrated in the accompanying drawings are not limited thereto but may be modified optionally within the scope of the effects of the present disclosure. Moreover, the embodiment may be modified optionally without departing from the scope of the object of the present disclosure.

For example, in the above embodiments, the method for manufacturing the bonded wafer 400 has been described, but the present disclosure may be applied to a method for manufacturing the first wafer 100 (a wafer) by changing an object to be adhered or bonded to the first wafer 100.

In such a method for manufacturing the first wafer 100, a supporting step is performed instead of the bonding step described above. In this supporting step, a supporting substrate is used instead of the second wafer 200. The supporting substrate is formed in a disk shape similar to that of the first wafer 100 and is not particularly limited; for example, a substrate equivalent to the first wafer 100 or the second wafer 200 may be used.

In the supporting step, a surface of the support substrate on one side is adhered or bonded to the first front surface 101 serving as the surface of the first wafer 100 on one side to arrange the first wafer 100 to be supported on the supporting substrate. The supporting step is performed similarly to the bonding step described above except that the supporting substrate is used in place of the second wafer 200.

In the method for manufacturing the first wafer 100, after the supporting step, a lateral-surface processing step is performed similarly to that in the first or third embodiment described above. In the lateral-surface processing step, the laser beam LB is emitted onto the lateral surface 103 of the first wafer 100 supported by the supporting substrate so that the lateral surface 103 is processed into a shape having a predetermined cross section. By being processed in the lateral-surface processing step, the diameter of the first wafer 100 may be reduced as shown in FIG. 1D, or the first wafer 100 may be formed into the shape having the cross section as shown in FIG. 3A where the diameter is varied partly within the range in the thickness direction, or into the shape having the cross section as shown in FIG. 2C where the both sides of the lateral surface 103 in the thickness direction are chamfered.

In the method for manufacturing the first wafer 100, a grinding step may be performed before or after the lateral-surface processing step, and such a grinding step is performed similarly to the grinding process performed in the surface processing step in the second and third embodiments described above. In the grinding step, the first back surface 102 serving as the surface of the first wafer 100 on the other side is ground so that the first wafer 100 is thinned.

According to the method for manufacturing the first wafer 100, by performing the supporting step, the lateral-surface processing step, and the grinding step, the first wafer 100 is manufactured so as to have a predetermined diameter and a predetermined thickness and have the lateral surface 103 formed into a predetermined cross-sectional shape.

According to the second embodiment, the chamfering step is performed after the surface processing step; however, the order may optionally be reversed so that the chamfering step may be performed before the surface processing step.

Further, in the first wafer 100 and the second wafer 200 of the bonded wafer 400, the surface to be adhered or bonded to another surface may be any of the front surfaces 101, 201 or the back surfaces 102, 202. Among the first wafer 100 and the second wafer 200, any surface to be adhered or bonded to another wafer is formed as the surface on one side, and the another surface on the opposite side is formed as the surface on the other side.

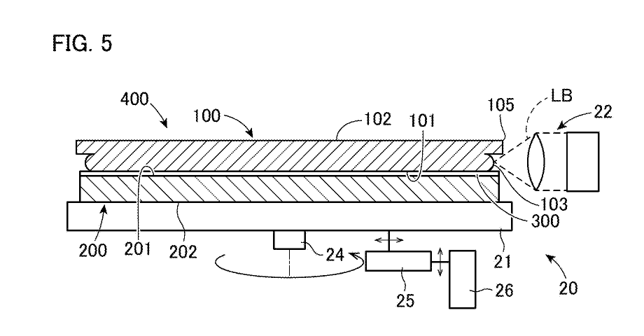

Moreover, in the lateral-surface processing step in the third embodiment, the cross-sectional shape of the lateral surface 103 of the first wafer 100 as shown in FIG. 5 may be formed by adjusting the driving of the horizontal movement mechanism 25 and the vertical movement mechanism 26 at the time of emission of the laser beam LB from the laser emitter 22. This cross-sectional shape may be formed so that the first wafer 100 has a chamfered cross-sectional shape eventually when the first wafer 100 is processed to the shape having the reduced diameter. By forming such a cross-sectional shape and thereafter performing the surface processing step, the first wafer 100 having the chamfered lateral surface 103 may be formed without performing the chamfering step, thereby shortening manufacturing time.

As described above, the present disclosure is advantageous in that the time required for processing an outer periphery of a first wafer which is bonded to a second wafer may be shortened.

What is claimed is:

1. A method for manufacturing a wafer, comprising:
a supporting step including adhering or bonding a surface of a first wafer on one side and a surface of a supporting substrate on one side to each other to arrange the first wafer to be supported on the supporting substrate;
a lateral-surface processing step including emitting a laser beam onto a lateral surface of the first wafer supported on the supporting substrate to form the lateral surface of the first wafer into a shape having a predetermined cross section; and
a grinding step including griding a surface of the first wafer on the other side, the grinding step being performed before or after the lateral-surface processing step.

2. A method for manufacturing a bonded wafer in which a first wafer and a second wafer are bonded, comprising:
a bonding step including bonding or adhering a surface of the first wafer on one side and a surface of the second wafer on one side to each other; and
a lateral-surface processing step including emitting a laser beam onto a lateral surface of the first wafer to process the lateral surface of the first wafer, the lateral-surface processing step being performed after the bonding step.

3. The method according to claim 2, further comprising a surface processing step including griding, polishing, or etching a surface of the first wafer on the other side, the surface processing step being performed before or after the lateral-surface processing step.

4. The method according to claim 3, further comprising a chamfering step including chamfering a corner between the lateral surface of the first wafer and the surface of the first wafer on the one side and a corner between the lateral surface of the first wafer and the surface of the first wafer on the other side, the chamfering step being performed before or after the surface processing step.

5. The method according to claim 2, wherein the lateral-surface processing step further includes chamfering a corner between the lateral surface of the first wafer and the surface of the first wafer on the one side and a corner between the lateral surface of the first wafer and the surface of the first wafer on the other side.
